(19) United States
(12) Patent Application Publication
(10) Pub. No.: US 2022/0050126 A1
(43) Pub. Date: Feb. 17, 2022

(54) PROBE CARD AND MANUFACTURING METHOD THEREFOR

(71) Applicant: POINT ENGINEERING CO., LTD., Asan (KR)

(72) Inventors: Bum Mo AHN, Suwon (KR); Seung Ho PARK, Hwaseong (KR); Sung Hyun BYUN, Hwaseong (KR)

(21) Appl. No.: 17/312,814

(22) PCT Filed: Nov. 26, 2019
(86) PCT No.: PCT/KR2019/016336

§ 371 Date: Jun. 10, 2021

(30) Foreign Application Priority Data
Dec. 11, 2018 (KR) 10-2018-0159137

(51) Int. Cl. G01R 1/073; G01R 3/00

(52) U.S. Cl. CPC G01R 1/07342; G01R 3/00

(57) ABSTRACT

Proposed are a probe card for performing a circuit test of a wafer and a manufacturing method therefor. More particularly, proposed are a probe card and a manufacturing method therefor, in which the process of inserting probe pins is eliminated.

### TECHNICAL FIELD

The present disclosure relates to a probe card for testing a pattern formed on a wafer and to a manufacturing method therefor.

### BACKGROUND ART

In general, a semiconductor manufacturing process largely includes a fabrication process for forming a pattern on a wafer, an electrical die sorting (EDS) process for testing electrical characteristics of respective chips constituting the wafer, and an assembly process for assembling the wafer on which a pattern is formed to individual chips.

Here, the EDS process is performed to detect defective chips among the chips constituting the wafer. In the EDS process, a probe card which applies electrical signals to the chips constituting the wafer and determines whether the chips are defective on the basis of signals checked from the applied electrical signals is mainly used.

The probe card has probes each applying an electrical signal to each of the chips constituting the wafer by making contact with a pattern of the chip. Each of the probes is brought into contact with an electrode pad of each device on the wafer and measures electrical properties that are output when a specific current is applied thereto.

In this case, the probe card has holes for allowing insertion of probe pins, and the probe pins are inserted into the holes and guided.

An example of a patent for a probe card is disclosed in Korean Patent No. 10-1255110 (hereinafter referred to as ‘Patent Document 1’).

Patent Document 1 is configured to include first and second base substrates made of a synthetic resin-based material, first and second guide members, and probe pins. Each of the first and second guide members of Patent Document 1 is a synthetic resin film or a ceramic substrate. The first guide member has holes arranged in vertical rows, and the second guide member has holes arranged in horizontal rows. The first and second guide members are sequentially stacked, and the probe pins are first inserted into the holes of the first guide member and then inserted into the holes of the second guide member. Since the first and second guide members are configured such that the respective holes thereof are formed in different directions, quadrangular holes are formed as the respective holes overlap each other. These quadrangular holes hold the probe pins in place.

However, since each of the first and second guide members of Patent Document 1 is the synthetic resin film or the ceramic substrate, transmittance thereof is low. This causes difficulty in inserting the probe pins into the holes formed in the first and second guide members.

In addition, in Patent Document 1, although the holes formed in the first and second guide members are configured to be formed in different directions in order to facilitate insertion of the probe pins, manufacturing efficiency is low in that the probe card is manufactured by inserting the probe pins into the holes formed in low-transmittance materials. This results in a problem in which the time and cost of manufacturing the probe card increase.

On the other hand, an example of a patent for a method that does not employ insertion of probe pins is disclosed in Japanese Patent No. 6151548 B2 (hereinafter referred to as ‘Patent Document 2’).

Patent Document 2 includes a substrate for a probe card having a surface wiring layer, and probe pins. In Patent document 2, the probe card is manufactured by joining one surfaces of probe terminals to a surface of the surface wiring layer.

However, Patent Document 2 is cumbersome in that the probe terminals have to be individually attached to the surface wiring layer. This increases manufacturing time, which may cause a reduction in work efficiency.

In addition, in Patent Document 2, since one surfaces of the probe terminals are joined to the surface wiring layer, joining force between the probe terminals and the surface wiring layer may be weak. Specifically, in Patent Document 2, top surfaces of the probe terminals are joined to the surface of the surface wiring layer. In other words, Patent Document 2 has a structure in which only the top surfaces of the probe terminals are supported by the surface of the surface wiring layer. In Patent Document 2, since only the surface of the surface wiring layer serves as a surface supporting the probe terminals, joining force and fixing force between the surface wiring layer and the probe terminals may be weak.

The probe terminals of Patent Document 2 are subjected to a test of electrical properties when allowed to make contact with terminals of a semiconductor device. In this case, such relatively weak bonding and fixing forces may cause an error in the test of electrical properties. The weak bonding and fixing forces may also cause a problem in which positional alignment of the probe terminals is changed to occur. As a result, the probe terminals may fail to properly make contact with the terminals of the semiconductor device, causing an error in circuit check function. In addition, the probe terminals may undesirably make contact with other portions of the semiconductor device, causing a problem of damage to the semiconductor device.

### DOCUMENTS OF RELATED ART

### Patent Document

(Patent Document 1) Korean Patent No. 10-1255110

(Patent Document 2) Japanese Patent No. 6151548 B2

### DISCLOSURE

### Technical Problem

Accordingly, the present disclosure has been made keeping in mind the above problems occurring in the related art, and an objective of the present disclosure is to provide a probe card having high manufacturing efficiency due to its structure that does not employ insertion of probe pins, and being capable of performing an effective wafer circuit test due to high fixing and joining force of the probe pins, and to provide a manufacturing method therefor.

### Technical Solution

An aspect of the present disclosure provides a probe card including: a probe pin including a horizontal portion and a vertical portion; and a probe pin support member including an anodic aluminum oxide film sheet supporting the horizontal portion from a top surface thereof, and a through-hole allowing the vertical portion to pass therethrough.

Furthermore, the vertical portion may protrude over a bottom portion of the probe pin support member.

Furthermore, the vertical portion may have a smaller width than the through-hole.

Furthermore, the probe card may further include a space transformer including a connection pad, wherein the connection pad may be electrically connected to the horizontal portion.

Furthermore, the space transformer may be formed by stacking a plurality of anodic aluminum oxide film sheets.

Another aspect of the present disclosure provides a method of manufacturing a probe card, the method including: a first step of etching at least a portion of an anodic aluminum oxide film sheet to form a first hole; a second step of forming a vertical portion by charging a conductive material in the first hole; a third step of forming a horizontal portion on a top surface of the anodic aluminum oxide film sheet so as to be connected to the vertical portion; and a fourth step of etching a portion of a bottom surface of the anodic aluminum oxide film sheet to allow the vertical portion to protrude over the anodic aluminum oxide film sheet, and removing a portion of the anodic aluminum oxide film sheet existing around the etched vertical portion to form a second hole.

Furthermore, the method may further include a fifth step of joining a space transformer including a connection pad to the horizontal portion.

Furthermore, the space transformer may be formed by stacking a plurality of anodic aluminum oxide film sheets.

### Advantageous Effects

A probe card and the manufacturing method therefor according to the present disclosure can increase the efficiency of manufacturing probe cards by easy provision of probe pins, and reduce the rate of contact failure with respect to circuit terminals by high bonding force and fixing force of the probe pins.

In addition, it is possible to improve the reliability of measurement by accurate connection of the probe pins to a contact position of a test object regardless of the influence of temperature.

### DESCRIPTION OF DRAWINGS

FIG. 1 is a view schematically illustrating a probe card according to a first exemplary embodiment of the present disclosure;

FIGS. 2A and 2B are enlarged views of a partial configuration of the probe card;

FIG. 3 is a view schematically illustrating a probe card according to a second exemplary embodiment of the present disclosure; and

FIGS. 4A-4E are views sequentially illustrating a manufacturing method for a probe card according to the present disclosure.

### MODE FOR INVENTION

Contents of the description below merely exemplify the principle of the present disclosure. Therefore, those of ordinary skill in the art may implement the theory of the disclosure and invent various apparatuses which are included within the concept and the scope of the disclosure even though it is not clearly explained or illustrated in the description. Furthermore, in principle, all the conditional terms and embodiments listed in this description are clearly intended for the purpose of understanding the concept of the present disclosure, and one should understand that this disclosure is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure will be described with reference to cross-sectional views and/or perspective views which schematically illustrate ideal embodiments of the present disclosure. For explicit and convenient description of the technical content, thicknesses and widths of members and regions in the figures may be exaggerated. Therefore, variations from the shapes of the illustrations as a result, for example, of manufacturing techniques and/or tolerances, are to be expected.

In addition, a limited number of holes are illustrated in the drawings. Thus, the embodiments should not be construed as limited to the particular shapes of regions illustrated herein but are to include deviations in shapes that result, for example, from manufacturing.

In describing various embodiments, the same reference numerals will be used throughout different embodiments and the description to refer to the same or like elements or parts. In addition, the configuration and operation already described in other embodiments will be omitted for convenience.

Hereinafter, exemplary embodiments of the present disclosure will be described in detail with reference to the accompanying drawings.

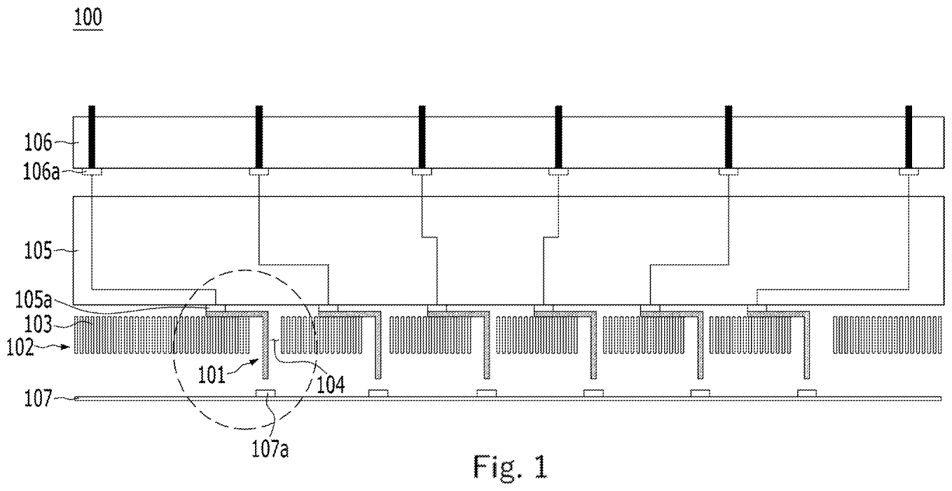

FIG. 1 is a view schematically illustrating a probe card 100 according to a first exemplary embodiment of the present disclosure. As illustrated in FIG. 1, the probe card 100 according to the present disclosure includes probe pins 101 brought into contact with circuit terminals 107a of a wafer (or semiconductor device), and a probe pin support member 102 supporting the probe pins 101, and a space transformer 105. The probe card 100 according to the present disclosure may check the state of a circuit disconnection or short circuit by bringing the probe pins 101 into contact with the circuit terminals 107a.

As illustrated in FIG. 1, the probe card 100 is positioned above the wafer 107 on which a circuit to be tested is formed. The probe card 100 is connected to a variety of external equipment and is moved up and down relative to the wafer 107 to check whether a normal circuit is formed. In FIG. 1, the probe card 100 is illustrated as being in a lifted state relative to the wafer 107.

As shown in FIG. 1, each of the probe pins 101 includes a horizontal portion 101a and a vertical portion 101b. An end of the horizontal portion 101a may be joined to a top portion of the vertical portion 101b. Thereby, the probe pin 101 may have a shape in which the top portion of the vertical portion 101b and the end of the horizontal portion 101a are connected to each other.

The horizontal portion 101a and the vertical portion 101b may be made of conductive materials. Thereby, when each of the probe pins 101 is brought into contact with an associated one of the circuit terminals 107a, an electrical signal applied to the probe card 100 may be transmitted to the wafer 107. Alternatively, a signal output from the wafer 107 may be received.

As illustrated in FIG. 1, the probe pins 101 may be supported by the probe pin support member 102. The probe pin support member 102 includes an anodic aluminum oxide film sheet 103 and through-holes 104.

The anodic aluminum oxide film sheet 103 may be made of an anodic aluminum oxide film having pores formed by anodizing a metal.

The pores of the anodic aluminum oxide film are formed in a regular arrangement. The anodic aluminum oxide film refers to a film formed by anodizing a metal that is a base material, and the pores refer to pores formed in the anodic aluminum oxide film during the process of forming the anodic aluminum oxide film by anodizing the metal. For example, in case where the metal as the base material is aluminum (Al) or an aluminum alloy, the anodization of the base material forms the anodic aluminum oxide film consisting of anodized aluminum oxide (Al₂O₃) on a surface of the base material. The anodic aluminum oxide film thus formed includes a barrier layer in which no pores are formed and a porous layer in which pores are formed. The barrier layer is positioned on the base material, and the porous layer is positioned on the barrier layer. In a state in which the anodic aluminum oxide film having the barrier layer and the porous layer is formed on the surface of the base material, when the base material is removed, only the anodic aluminum oxide film consisting of anodized aluminum oxide (Al₂O₃) remains.

The resulting anodic aluminum oxide film has the pores that have a uniform diameter, are formed in a vertical shape, and have a regular arrangement. Therefore, when the barrier layer is removed, a structure in which the pores vertically pass through the anodic aluminum oxide film from top to bottom is formed.

The anodic aluminum oxide film has insulating properties. In other words, the anodic aluminum oxide film sheet 103 has insulating properties. The anodic aluminum oxide film sheet 103 constituting the probe pin support member 102 may support the probe pins 101. In this case, the anodic aluminum oxide film sheet 103 having insulating properties may prevent conduction from occurring in a configuration other than the probe pins 101.

The anodic aluminum oxide film has a coefficient of thermal expansion of 2 to 3 ppm/° C. This may result in a small degree of deformation due to temperature. For example, an EDS process is performed under a high-temperature environment. In this case, the anodic aluminum oxide film sheet 103 composed of the anodic aluminum oxide film has high thermal durability due to its relatively low coefficient of thermal expansion. Therefore, when used in the EDS process performed under a high-temperature environment, the anodic aluminum oxide film sheet 103 may not be easily deformed. In addition, the anodic aluminum oxide film sheet 103 may perform a function of thermal insulation. Thereby, configurations provided around the probe pin support member 102 may be protected from a high-temperature environment.

The probe pin support member 102 includes the through-holes 104. The through-holes 104 pass through top and bottom surfaces of the anodic aluminum oxide film sheet 103 described above. The vertical portion 101b of each of the probe pins 101 passes through an associated one of the through-holes 104. In this case, the vertical portion 101b protrudes over a bottom portion of the through-hole 104. The through-hole 104 passes through the anodic aluminum oxide film sheet 103 of the probe pin support member 102 from top and bottom. Therefore, the vertical portion 101b may pass through the through-hole 104 to protrude over a bottom portion of the probe pin support member 102.

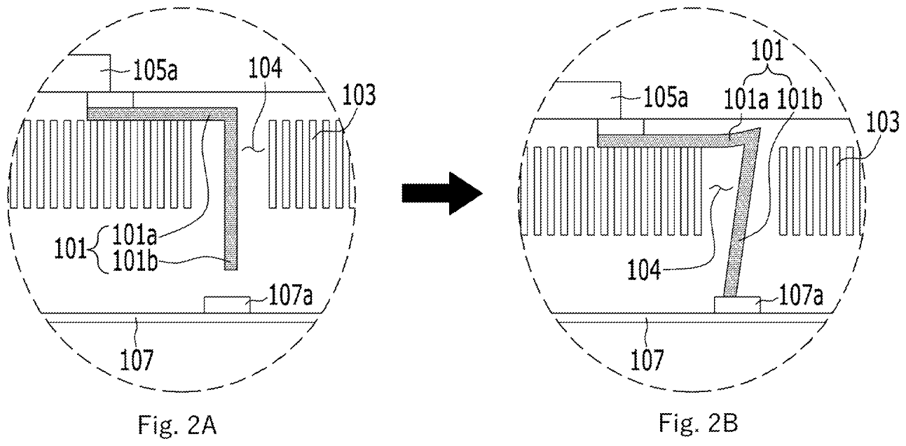

In addition, the through-hole 104 is configured to have a larger width than the vertical portion 101b. In other words, the vertical portion 101b is configured to have a smaller width than the through-hole 104. The vertical portion 101b is a portion that is brought into direct contact with an associated one of the circuit terminals 107a. When the vertical portion 101b of each of the probe pins 101 is brought into contact with an associated one of the circuit terminals 107a, a connecting portion between the horizontal portion 101a and the vertical portion 101b of the probe pin 101 may be elastically deformed. In consideration of such elastic deformation, the through-hole 104 may have a larger width than the vertical portion 101b. This will be described in detail below with reference to FIGS. 2A and 2B.

FIGS. 2A and 2B are partial enlarged views of the probe pin support member 102. FIG. 2A is a view illustrating a state before the probe pin 101 and the circuit terminal 107a are brought into contact with each other, and FIG. 2B is a view illustrating a state after the probe pin 101 and the circuit terminal 107a are brought into contact with each other.

As illustrated in FIGS. 2A and 2B, the probe pin support member 102 supports the horizontal portion 101a of the probe pin 101 on a top surface of the anodic aluminum oxide film sheet 103, and allows the vertical portion 101b of the probe pin 101 to pass through the through-hole 104. In this case, the vertical portion 101b has a smaller width than the through-hole 104. Therefore, a free space is formed around the vertical portion 101b passing through the through-hole 104. This free space may accommodate elastic deformation of the horizontal portion 101a and the vertical portion 101b. Here, the connecting portion between the horizontal portion 101a and the vertical portion 101b may be a junction in which the end of the horizontal portion 101a of the probe pin 101 and the top portion of the vertical portion 101b are joined to each other.

As illustrated in FIG. 2B, the probe pin 101 is brought into contact with the circuit terminal 107a. The probe pin 101 is elastically deformed while making contact with the circuit terminal 107a. Specifically, as the vertical portion 101b is brought into contact with the circuit terminal 107a, the vertical portion 101b and the connecting portion of the probe pin 101 are elastically deformed. In consideration of such elastic deformation of the probe pin 101 upon the contact between the probe pin 101 and the circuit terminal 107a, the through-hole 104 may have a larger width than the vertical portion 101b. This provides a free space. The vertical portion 101b may be elastically deformed freely within the range of the free space. For example, when a through-hole has the same width as a probe pin, the probe pin may be inserted into and fixed to the through-hole. With this structure, it is impossible for the probe pin to perform a buffer function upon contact with the circuit terminal, which may cause damage to the circuit terminal. However, in the present disclosure, by realizing a structure that can accommodate free elastic deformation of the probe pin 101 upon the contact between the probe pin 101 and the circuit terminal 107a, thereby preventing the circuit terminal 107a from being damaged. This may result in an increase in physical reliability in checking circuits of the wafer 107.

As described above, the probe pin support member 102 may be configured in a structure that supports the respective horizontal portions 101a of the probe pins 101 on the top surface of the anodic aluminum oxide film sheet 103, and allows the respective vertical portions 101b to pass through the through-holes 104. Also, the probe pin support member 102 may be configured in a structure that supports each of the probe pins 101 at a position between the horizontal portion 101a and the vertical portion 101b of the probe pin 101.

The probe pin support member 102 has a coefficient of thermal expansion of 2 to 3 ppm/° C. because it is constituted by the anodic aluminum oxide film sheet 103. In the probe card 100 according to the present disclosure having the probe pin support member 102, a fixed position of each of the probe pins 101 may be constant regardless of temperature change in the EDS process performed under a high-temperature environment. As a result, it is possible to prevent a functional error due to a fixed position error of the probe pin 101.

In addition, the probe pin support member 102 according to the present disclosure has a coefficient of thermal expansion similar to that of the wafer 107. This reduces the problem of contact failure between the probe pins 101 and the circuit terminals 107a. Conventionally, probe pins are provided on a probe card made of a ceramic material composed of a sintered body of alumina. In the case of the ceramic material composed of the sintered body of alumina, its coefficient of thermal expansion is different from that of a silicon wafer, which causes a contact failure problem when temperature changes. However, the coefficient of thermal expansion of the probe pin support member 102 according to the present disclosure is 2 to 3 ppm/° C., which is similar to that of 3 ppm/° C. of the wafer 107. Therefore, when the probe pin support member 102 and the wafer 107 are thermally expanded under the influence of temperature, their coefficients of thermal expansion may be similar to each other. This ensures that even if a predetermined position error occurs in each of the probe pins 101 and each of the circuit terminals 107a of the wafer 107, a similar position error range may be obtained. As a result, it is possible to prevent the problem of contact failure between the probe pin 101 and the circuit terminal 107a due to a contact position error.

Referring back to FIG. 1, the probe card 100 may include the space transformer 105 having connection pads 105a. The space transformer 105 may be provided between a PCB substrate 106 and the probe pin support member 102. The space transformer 105 may compensate for a pitch difference between substrate terminals 106a of the PCB substrate 106 and the probe pins 101.

As illustrated in FIG. 1, the space transformer 105 may be positioned on the probe pin support member 102, but may be provided below the PCB substrate 106. In other words, the space transformer 105 may be provided between the probe pin support member 102 and the PCB substrate 106.

The space transformer 105 has the connection pads 105a on a bottom portion thereof. Therefore, when the space transformer 105 is provided on the probe pin support member 102, each of the connection pads 105a and an associated one of the horizontal portions 101a of the probe pins 101 may be brought into contact with each other. The horizontal portions 101a of the probe pins 101 may be respectively brought into contact with and joined to the connection pads 105a of the space transformer 105. This allows electrical connection of the space transformer 105 to the probe pins 101. The joining between the connection pads 105a and the horizontal portions 101a may be implemented using a conventional joining technique. In addition, an adhesive layer (not illustrated) may be provided between the space transformer 105 and the probe pin support member 102 to join the same to each other. The adhesive layer may be made of a thermoplastic resin, and may be combined with top and bottom members by heating and compressing the top and bottom members.

The connection pads 105a are provided in number corresponding to the number of probe pins 101. The connection pads 105a may be collectively joined to the horizontal portions 101a of the probe pins 101. In a conventional probe card, each probe pin has to be individually attached to an associated one of connection pads of a space transformer, which is cumbersome. However, the probe pins 101 according to the present disclosure are each composed of the horizontal portion 101a and the vertical portion 101b and are supported by the probe pin support member 102. In this case, the respective horizontal portions 101a allow the probe pins 101 to be stably supported by the probe pin support member 102. The probe pins 101 may have a structure supported by the probe pin support member 102 so as to be collectively joined to the connection pads 105a. In the conventional case, there is provided no member supporting probe pins, the probe pins have to be joined to the connection pads 105a one by one. However, the present disclosure has a structure allowing the probe pins 101 and the connection pads 105a to be collectively joined to each other. This obtains the effect of increasing the efficiency of manufacturing probe cards.

As described above, the connection pads 105a are collectively joined to the horizontal portions 101a of the probe pins 101. In this case, the horizontal portions 101a of the probe pins 101 are supported on the top surface of the probe pin support member 102 and supported on respective bottom surfaces of the connection pads 105a. In other words, top and bottom surfaces of each of the horizontal portions 101a are supported and fixed by separate members.

In the present disclosure, with such a structure for fixing the probe pins 101, it is possible to improve fixing force and joining force. In the conventional case, one surface of each probe pin is joined to one surface of an associated connection pad. As a result of contact between one surface of the probe pin and one surface of the connection pad, one joining surface is formed. Conventionally, joining force and fixing force are formed only on one joining surface as described above. In this case, however, the probe pin is fixed by this one joining surface. Therefore, when the joining force of the joining surface decreases, the fixing force also decreases thereby. This may result in a change in positional alignment of probe pins. In addition, separation of the probe pins may occur. However, in the present disclosure, top and bottom surfaces of the probe pins 101 are fixed and supported by separate members. Specifically, the connection pads 105a of the space transformer 105 fixedly support the probe pins 101 on the respective top surfaces of the horizontal portions 101a of the probe pins 101. In addition, the probe pin support member 102 fixedly supports the probe pins 101 on the respective bottom surfaces of the horizontal portions 101a of the probe pins 101. This improves the joining force and fixing force of the probe pins 101. According to the present disclosure, it is possible to realize high bonding force and fixing force to fixedly support the probe pins 101 in place. This prevents the problem in which the position alignment of the probe pins 101 is changed. As a result, it is possible to reduce the rate of contact failure occurring between the probe pins 101 and the circuit terminals 107a.

In addition, the present disclosure can prevent the problem in which the prop pins 101 peel off. Conventionally, joining positions where probe pins are fixed are exposed to outside, and these joining positions are positions directly influenced by thermal stress due to the surrounding thermal environment. Such thermal stress causes the probe pins to peel off. However, according to the exemplary embodiment of the present disclosure, since the horizontal portions 101a of the probe pins 101 by which the probe pins 101 are fixed are located inside the anodic aluminum oxide film sheet 103, fixed positions of the probe pins 101 are not exposed to outside so as to have minimized influence from the surrounding thermal environment. Thereby, it is possible to resolve the problem of peel-off of the probe pins 101 due to thermal stress.

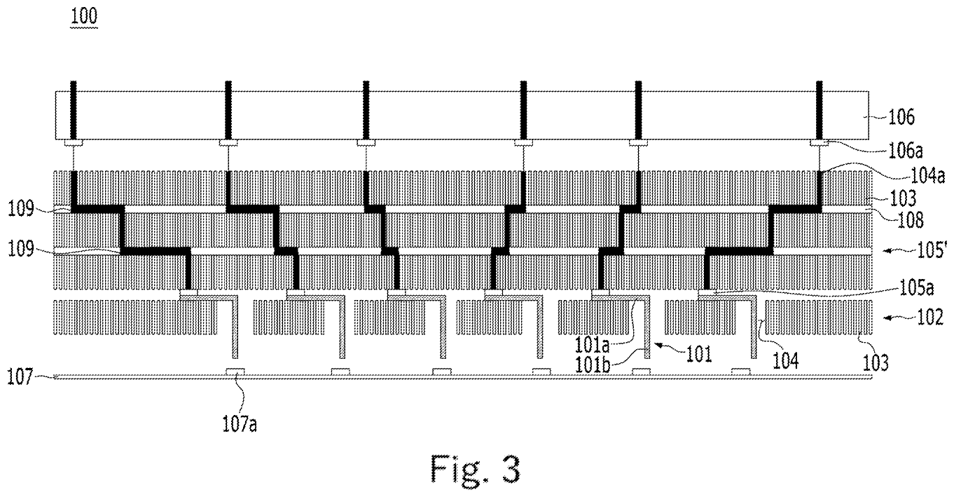

Hereinafter, a second exemplary embodiment of the present disclosure will be described with reference to FIG. 3. A probe card 100 according to the second exemplary embodiment is different from the first exemplary embodiment in that it includes a space transformer 105′ composed of a plurality of anodic aluminum oxide film sheets 103. The second exemplary embodiment described below will be mainly described with respect to characteristic components compared to the first exemplary embodiment, and detailed descriptions of the same or similar components as those of the first exemplary embodiment will be omitted.

FIG. 3 is a view schematically illustrating the probe card 100 according to the second exemplary embodiment of the present disclosure. As illustrated in FIG. 3, the probe card 100 of the second exemplary embodiment includes probe pins 101, a probe pin support member 102, and a space transformer 105′.

As illustrated in FIG. 3, the space transformer 105′ is provided on the probe pin support member 102. The space transformer 105′ may be provided between a PCB substrate 106 and the probe pin support member 102 to compensate for a pitch difference between substrate terminals 106a of the PCB substrate 106 and the probe pins 101.

The space transformer 105′ included in the probe card 100 of the second exemplary embodiment is formed by stacking the plurality of anodic aluminum oxide film sheets 103. In the present disclosure, as an example, the space transformer 105′ is described as being formed by stacking three anodic aluminum oxide film sheets 103. However, the number of stacked anodic aluminum oxide film sheets 103 is not limited thereto.

The three anodic aluminum oxide film sheets 103 may include a first anodic aluminum oxide film sheet, a second anodic aluminum oxide film sheet, and a third anodic aluminum oxide film sheet stacked from the lower side of FIG. 3. The first to third anodic aluminum oxide film sheets may be sequentially stacked on top of each other.

Each of the anodic aluminum oxide film sheets 103 may have through-holes formed therein and each allowing a via conductor 104a to be charged therein. The via conductor 104a may be made of at least one of a metal material such as solder, copper, silver, tin, bismuth, indium, chromium, nickel, or titanium, and an alloy material of these metals. The via conductor 104a may be charged in each of the through-holes by a method such as sputtering, deposition, plating, or charging of conductor paste.

As illustrated in FIG. 3, the respective via conductors 104a of the first anodic aluminum oxide film sheet have a pitch so as to be electrically connected to connection pads 105a. Meanwhile, the respective via conductors 104a of the third anodic aluminum oxide film sheet have a pitch so as to be electrically connected to the substrate terminals 106a of the PCB substrate 106. The respective via conductors 104a of the second anodic aluminum oxide film sheet are provided to compensate for such a difference between the pitches of the via conductors 104a of the first anodic aluminum oxide film sheet and the third anodic aluminum oxide film sheet. An internal wiring layer 109 is formed on a top surface of the first anodic aluminum oxide film sheet. The internal wiring layer 109 may be joined to the top of the via conductors 104a so as to be electrically connected to the via conductors 104a of the second anodic aluminum oxide film sheet stacked on the first anodic aluminum oxide film sheet. In addition, an internal wiring layer 109 is also formed on a top surface of the second anodic aluminum oxide film sheet. The internal wiring layer 109 formed on the second anodic aluminum oxide film sheet may be electrically connected to the via conductors 104a of the third anodic aluminum oxide film sheet.

The plurality of anodic aluminum oxide film sheets 103 may be joined to each other through respective anisotropic conductive materials 108. Each of the anisotropic conductive materials 108 may be one of an anisotropic conductive film (ACF) and an anisotropic conductive adhesive (ACA). The anisotropic conductive materials 108 for joining the plurality of anodic aluminum oxide film sheets 103 may include conductive particles. In this case, since the anodic aluminum oxide film sheets 103 have insulating properties, electricity cannot flow in the horizontal direction, but can flow in the vertical direction through the conductive particles. Therefore, the via conductors 104a of vertically adjacent anodic aluminum oxide film sheets 103 and the internal wiring layer 109 between the sheets are electrically connected to each other through the conductive particles.

On the other hand, the plurality of anodic aluminum oxide film sheets 103 may be joined to each other by respective adhesive layers each made of a thermoplastic resin and joining vertically adjacent anodic aluminum oxide film sheets 103.

On the other hand, the plurality of anodic aluminum oxide film sheets 103 may be joined to each other by respective thin film conductor layers. Each of the thin film conductor layers is made of a metal material such as copper, silver, palladium, gold, platinum, aluminum, chromium, nickel, cobalt, or titanium. Also, an alloy material of these metals may be used.

When the plurality of plurality of anodic aluminum oxide film sheets 103 are joined to each other by the thin film conductor layers, the thin film conductor layers may be formed by a method such as sputtering, vapor deposition, plating, or the like. In this case, trimming processing such as masking or etching may be performed as needed so that the respective via conductors 104a of the anodic aluminum oxide film sheets 103 are electrically connected to each other.

The probe pin support member 102 including an anodic aluminum oxide film sheet 103 and through-holes 104 is provided under the space transformer 105′. The probe pin support member 102 supports a horizontal portion 101a of each of the probe pins 101 on a top surface thereof. Therefore, each of the respective horizontal portions 101a and an associated one of the connection pads 105a of the space transformer 105′ may be joined to be electrically connected to each other. A vertical portion 101b of each of the probe pins 101 passes through an associated one of the through-holes 104.

As described above, the space transformer 105′ is composed of the plurality of anodic aluminum oxide film sheets 103. The probe pin support member 102 is also composed of the anodic aluminum oxide film sheet 103. Therefore, the space transformer 105′ and the probe pin support member 102 have the same coefficients of thermal expansion. A conventional wiring substrate made of a ceramic material composed of a sintered body of alumina is manufactured by performing heating and sintering for about 24 hours at a temperature at which alumina can be sintered (about 1600° C.), a distortion phenomenon during sintering and positional misalignment due to plastic shrinkage occurs. On the contrary, the plurality of stacked anodic aluminum oxide film sheets 103 according to the present disclosure does not require a separate sintering process, so the present disclosure eliminates such conventional problems of distortion or positional misalignment due to plastic shrinkage. This minimizes positional misalignment between the space transformer 105′ and the probe pin support member 102, thereby making it possible to manufacture the probe card 100 more reliably.

When an EDS process is performed by the probe card 100 including the space transformer 105′ and the probe pin support member 102, it is possible to prevent a delamination phenomenon from occurring at a joining interface. Here, the joining interface may be an interface between a top surface of each of the horizontal portions 101a and the connection pad 105a joined thereto. Also, the joining interface may be an interface between a bottom surface of each of the horizontal portions 101a and the anodic aluminum oxide film sheet 103 of the probe pin support member 102 joined thereto. Conventionally, a multilayer wiring substrate is composed of a resin insulating layer and a ceramic substrate to perform the function of a space transformer. However, the multilayer wiring substrate is formed by stacking and joining dissimilar materials, which causes an interlayer delamination phenomenon to occur at a joining interface between the resin insulating layer and the ceramic substrate. The resin insulating layer and the ceramic substrate have different coefficients of thermal expansion. Therefore, their coefficients of thermal expansion due to thermal influence in an EDS process are different. This causes stress to be created at the joining interface between the resin insulating layer and the ceramic substrate. As a result, the interlayer delamination phenomenon occurs. However, in the present disclosure, the space transformer 105′ and the probe pin support member 102 are each composed of the anodic aluminum oxide film sheet 103 so as to have the same coefficient of thermal expansion. Therefore, their coefficients of thermal expansion due to thermal influence in the EDS process are the same. This minimizes residual stress at the joining interface, thereby preventing the interlayer delamination phenomenon from occurring at the joining interface.

In addition, when checking circuit terminals 107a under a high-temperature environment and a low-temperature environment, the probe card 100 including the space transformer 105′ and the probe pin support member 102, each composed of the anodic aluminum oxide film sheet 103, does not undergo positional misalignment with respect to the circuit terminals 107a. The anodic aluminum oxide film sheet 103 constituting the space transformer 105′ and the probe pin support member 102 has a coefficient of thermal expansion similar to that of a wafer 107. Accordingly, when performing a circuit check under a high-temperature environment and a low-temperature environment, the probe card 100 may have a coefficient of thermal expansion similar to that of the wafer. This prevents positional misalignment with respect to the circuit terminals 107a. As a result, it is possible to obtain the effect of reducing the rate of contact failure with respect to the circuit terminals 107a.

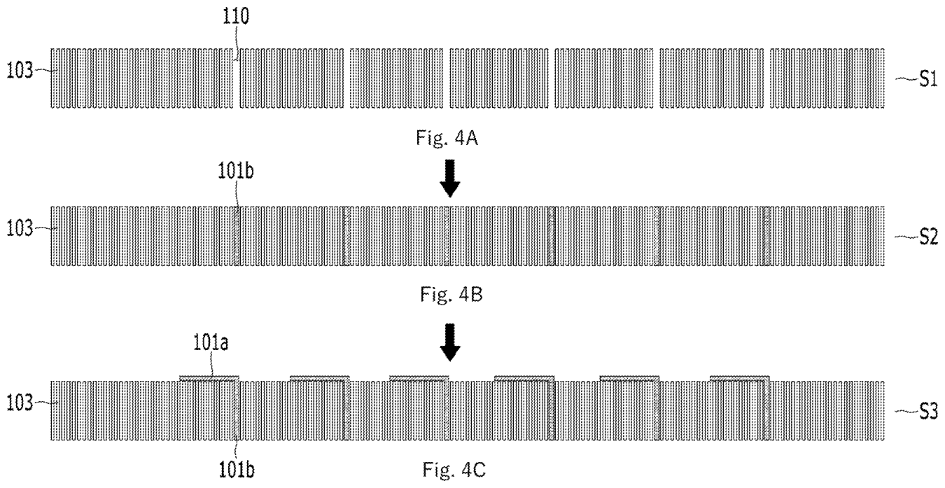

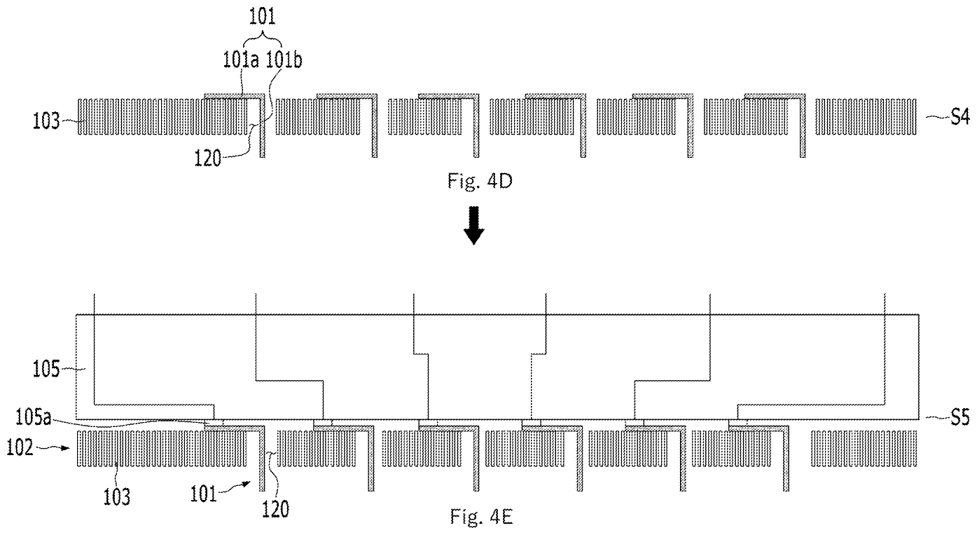

FIGS. 4A-4E is a view sequentially illustrating a manufacturing method for a probe card 100 according to the present disclosure. FIGS. 4A-4E exemplarily illustrates the probe card 100 of the first exemplary embodiment.

The manufacturing method for the probe card includes a first step S1 of forming first holes 110 in an anodic aluminum oxide film sheet 103, a second step S2 of forming vertical portions 101b, a third step S3 of forming horizontal portions 101a, a fourth step of forming second holes 120, and a fifth step S5 of joining a space transformer 105.

As illustrated in FIG. 4A, the anodic aluminum oxide film sheet 103 formed by anodizing a metal is provided. Then, the first holes 110 are formed in the anodic aluminum oxide film sheet 103 by etching. The first holes 11 may pass through the anodic aluminum oxide film sheet 103 from top to bottom. Each of the first holes 110 may have an arbitrary width. The first holes 110 may be etched to allow the vertical portions 101b of probe pins 101 to be formed therein. In the anodic aluminum oxide film sheet 103, first holes 110 having a narrower pitch than the first holes 110 illustrated in FIG. 4A may be formed by etching. This allows provision of probe pins 101 with a narrow pitch. As a result, effective connection of the probe pins to fine terminals is ensured. As described above, the first step S1 of forming the first holes 110 in the anodic aluminum oxide film sheet 103 is performed.

Then, the second step S2 of charging a conductive material in the first holes 110 is performed. As illustrated in FIG. 4B, the conductive material is charged in the first holes 110. This results in formation of the vertical portions 101b. Each of the vertical portions 101b is a portion that constitutes each of the probe pins 101 and is brought into contact with an associated one of circuit terminals 107a. The conductive material forming the vertical portions 101b includes, but is not limited to, at least one of a metal material such as solder, copper, silver, tin, bismuth, indium, chromium nickel, or titanium, and an alloy material of these metals. The vertical portions 101b made of the above conductive material may be electrically connected to the circuit terminals 107a.

Then, as illustrated in FIG. 4C, the third step S3 of forming the horizontal portions 101a so as to be connected to the vertical portions 101b is performed. As illustrated in FIG. 4C, the horizontal portions 101a are formed on a top surface of the anodic aluminum oxide film sheet 103 so as to be connected to respective top portions of the vertical portions 101b. As in the case of the vertical portions 101b, the horizontal portions 101a may be made of a conductive material. The horizontal portions 101a may be formed such that respective ends thereof are connected to the top portions of the vertical portions 101b.

The fourth step S4 of forming the second holes 120 is then performed. As illustrated in FIG. 4D, at least a portion of the anodic aluminum oxide film sheet 103 existing around each of the vertical portions 101b is vertically etched. This results in formation of the second holes 120. The second holes 120 may be through-holes 104 allowing the vertical portions 101b to pass therethrough. In addition, a portion of a bottom surface of the anodic aluminum oxide film sheet 103 is horizontally etched. This allows the vertical portions 101b to protrude over the anodic aluminum oxide film sheet 103. The vertical portions 101b may be brought into contact with the circuit terminals 107a through protruding portions thereof.

Then, the fifth step S5 of joining the space transformer 105 is performed. As illustrated in FIG. 4E, the space transformer 105 having connection pads 105a is provided. Then, the connection pads 105a are respectively joined to the horizontal portions 101a. In this case, the connection pads 105a may be collectively joined to the horizontal portions 101a.

Meanwhile, in the fifth step S5, a space transformer 105′ including a plurality of anodic aluminum oxide film sheets 103 may be provided. In this case, the space transformer 105′ may be formed by joining the plurality of anodic aluminum oxide film sheets 103. The plurality of anodic aluminum oxide film sheets 103 may include a via conductor 104a, an internal wiring layer 109, and an anisotropic conductive material 108 (or a thin film conductor layer). With these configurations, the plurality of anodic aluminum oxide film sheets 103 may be electrically connected to each other. As illustrated in FIG. 4E, the connection pads 105a of the space transformer 105′ may be collectively joined to the horizontal portions 101a. The space transformer 105′ composed of the plurality of anodic aluminum oxide film sheets 103 may be joined to the horizontal portions 101a, thereby manufacturing the probe card 100 according to the second exemplary embodiment.

In the probe card 100 according to the present disclosure, the first and second holes 110 and 120 for providing the probe pins 101 may be formed by etching. The anodic aluminum oxide film sheet 103 made of an anodic aluminum oxide film may be etched to chemically form the first and second holes 110 and 120. This makes it easy to form holes with a narrow pitch. In the conventional case, holes for providing probe pins are formed in a substrate made of a ceramic material composed of a sintered body of alumina. In this case, the holes are formed through laser processing. Laser processing is a method of thermally deforming positions where the holes are to be formed. Therefore, an appropriate separation distance has to be considered when forming the holes. In other words, in the conventional case, because the appropriate separation distance has to be considered when forming the holes, this makes it difficult to form holes with a narrow pitch. However, in the present disclosure, it is possible to easily form the narrow-pitch holes by etching the anodic aluminum oxide film sheet 103. This allows the probe pins 101 to be formed with a very narrow pitch. In the present disclosure, as described above, it is possible to provide the probe pins 101 of a narrow pitch. It is thus possible to ensure easy connection of the probe pins to fine terminals of a highly integrated and miniaturized semiconductor device. In other words, according to the present disclosure, even if circuit terminals of a test object are formed with a narrow pitch, it is possible to provide the probe pins 101 of a suitable pitch to correspond with the narrow pitch.

Since the present disclosure can provide the probe pins 101 of a narrow pitch as described above, this ensures effective connection of the probe pins to fine terminals. In addition, the present disclosure provides a structure allowing the probe pins 101 to be stably supported. This improves joining force and fixing force of the probe pins 101, thereby reducing the rate of contact failure with respect to the circuit terminals 107a. In addition, in the present disclosure, by providing a configuration having a coefficient of thermal expansion similar to that of the test object, it is possible to prevent positional misalignment between the circuit terminals 107a and the probe pins 101. This increases the accuracy of contact positions between the circuit terminals 107a and the probe pins 101. As a result, it is possible increase the reliability of measurement.

As described above, the present disclosure has been described with reference to the exemplary embodiments. However, those skilled in the art will appreciate that various modifications, additions, and substitutions are possible, without departing from the scope and spirit of the present disclosure as disclosed in the following claims.

[Description of the Reference Numerals
in the Drawings]

| | |
|---|---|
| 100: | probe card |
| 101: | probe pin |
| 101a: | horizontal portion |
| 101b: | vertical portion |
| 102: | probe pin support member |
| 103: | anodic aluminum oxide film sheet |
| 104: | through-hole |
| 104a: | via conductor |
| 105, 105′: | space transformer |
| 105a: | connection pad |
| 106: | PCB substrate |
| 106a: | substrate terminal |
| 107: | wafer |
| 107a: | circuit terminal |
| 108: | anisotropic conductive material |
| 109: | internal wiring layer |
| 110: | first hole |
| 120: | second hole |

1. A probe card comprising:
a probe pin including a horizontal portion and a vertical portion; and
a probe pin support member including an anodic aluminum oxide film sheet supporting the horizontal portion from a top surface thereof, and a through-hole allowing the vertical portion to pass therethrough.

2. The probe card of claim 1, wherein the vertical portion protrudes over a bottom portion of the probe pin support member.

3. The probe card of claim 1, wherein the vertical portion has a smaller width than the through-hole.

4. The probe card of claim 1, further comprising:
a space transformer including a connection pad,
wherein the connection pad is electrically connected to the horizontal portion.

5. The probe card of claim 4, wherein the space transformer is formed by stacking a plurality of anodic aluminum oxide film sheets.

6. A method of manufacturing a probe card, the method comprising:
a first step of etching at least a portion of an anodic aluminum oxide film sheet to form a first hole;
a second step of forming a vertical portion by charging a conductive material in the first hole;
a third step of forming a horizontal portion on a top surface of the anodic aluminum oxide film sheet so as to be connected to the vertical portion; and
a fourth step of etching a portion of a bottom surface of the anodic aluminum oxide film sheet to allow the vertical portion to protrude over the anodic aluminum oxide film sheet, and removing a portion of the anodic aluminum oxide film sheet existing around the etched vertical portion to form a second hole.

7. The method of claim 6, further comprising: a fifth step of joining a space transformer including a connection pad to the horizontal portion.

8. The method of claim 7, wherein the space transformer is formed by stacking a plurality of anodic aluminum oxide film sheets.
